(19) United States
(12) Patent Application Publication
(10) Pub. No.: US 2019/0194014 A1
(43) Pub. Date: Jun. 27, 2019

(54) PRESSURE SENSOR STRUCTURE CONFIGURED FOR WAFER-LEVEL CALIBRATION

(71) Applicant: Continental Automotive Systems, Inc., Auburn Hills, MI (US)

(72) Inventor: Wlodzimierz Czarnocki, Hoffman Estates, IL (US)

(21) Appl. No.: 16/225,176

(22) Filed: Dec. 19, 2018

Related U.S. Application Data
(60) Provisional application No. 62/609,084, filed on Dec. 21, 2017.

(51) Int. Cl. B81B 7/02; B81B 7/00

(52) U.S. Cl. CPC B81B 7/02; B81B 7/007; B81C 2203/0792; B81B 2207/091; B81B 2207/012; B81B 2201/0264

(57) ABSTRACT

A wafer structure configured for wafer-level calibration of a plurality of pressure sensors, the wafer structure includes: a microelectromechanical systems (MEMS) wafer that includes a plurality of MEMS dice that are separated by a plurality of MEMS-wafer dicing areas; an application-specific integrated circuit (ASIC) wafer that includes a plurality of ASIC-wafer dice that are separated by a plurality of ASIC-wafer dicing areas; a Film on Wafer (FOW) that bonds the MEMS wafer to the ASIC wafer; a plurality of thru silicon vias (TSVs) extending through the ASIC wafer; and a plurality of metallizations extending through the FOW thereby creating an electrical connection between the ASIC wafer and the MEMS wafer thereby enabling wafer-level calibration of the plurality of pressure sensors. The MEMS wafer and the ASIC wafer may each include alignment features for aligning the MEMS wafer with the ASIC wafer.

### BACKGROUND

Pressure sensors, including monolithic pressure sensors, are individually calibrated, or calibrated in small groups, for example 8 pressure sensors at a time, as fully assembled modules. A monolithic pressure sensor has both MEMS (Microelectromechanical systems) and ASIC (application-specific integrated circuit) co-processed (i.e., both created) on the same wafer.

Calibration requires application of precise pressure and exposure to well controlled temperature of each pressure sensor which, in turn, requires bulky, complicated, and expensive test equipment, including a connector and a communication board for each pressure sensor being simultaneously calibrated.

Improved techniques for calibrating pressure sensors more efficiently would be an improvement.

### BRIEF SUMMARY

Embodiments of the invention are directed to a wafer structure configured for wafer-level calibration of a plurality of pressure sensors, the wafer structure includes: a microelectromechanical systems (MEMS) wafer that includes a plurality of MEMS dice that are separated by a plurality of MEMS-wafer dicing areas; an application-specific integrated circuit (ASIC) wafer that includes a plurality of ASIC-wafer dice that are separated by a plurality of ASIC-wafer dicing areas; a Film on Wafer (FOW) that bonds the MEMS wafer to the ASIC wafer; a plurality of thru silicon vias (TSVs) extending through the ASIC wafer; and a plurality of metallizations extending through the FOW thereby creating an electrical connection between the ASIC wafer and the MEMS wafer thereby enabling wafer-level calibration of the plurality of pressure sensors. The MEMS wafer and the ASIC wafer may each include alignment features for aligning the MEMS wafer with the ASIC wafer.

### BRIEF DESCRIPTION OF THE DRAWINGS

FIG. 1 shows a wafer structure for a differential sensor that can be used for wafer-level calibration of pressure sensors.

FIG. 2 shows a wafer structure for an absolute sensor that can be used for wafer-level calibration of pressure sensors.

FIG. 3 shows wafer-level calibration of a wafer structure for an absolute sensor that can be used for wafer-level calibration of pressure sensors.

FIG. 4 shows wafer-level calibration of a wafer structure for a differential sensor that can be used for wafer-level calibration of pressure sensors.

FIG. 5 shows an after-sawing individual differential pressure sensor in accordance with embodiments of the invention.

FIG. 6 shows an after-sawing individual absolute pressure sensor in accordance with embodiments of the invention.

FIG. 7 shows an application of after-sawing individual differential pressure sensor in accordance with embodiments of the invention.

FIG. 8 shows an application of after-sawing individual absolute pressure sensor in accordance with embodiments of the invention.

FIG. 9 shows a wafer structure for a differential sensor that can be used for wafer-level calibration of pressure sensors and that is similar to the wafer structure of FIG. 1.

FIG. 10 shows a wafer structure for an absolute sensor that can be used for wafer-level calibration of pressure sensors and that is similar to the wafer structure of FIG. 2.

### DETAILED DESCRIPTION

Wafer-level calibration offers calibration of many devices “at the same time”. For example, pressure and temperature are applied to many sensors (e.g., 4,000 sensors on a single wafer) at the same time, and multiple (e.g., 16) sensors may be probed (i.e., an electrical connection may be established) simultaneously. This offers speedy, cost-reduced calibration relative to the individual calibration procedure described above.

Wafer-level calibration would require a wafer structure suitable for this kind of operation. Such a wafer structure may be created at a packaging foundry.

As such, embodiments of the invention result in cost-effective structure for calibration of pressure sensors at the wafer level by leveraging advantages, including cost efficiencies, of processing MEMS wafers and ASIC wafers at their own separate dedicated foundries.

To create such a wafer structure, post-processing at a packaging foundry, may comprise the following steps:
Differential or Absolute MEMS wafers come in as finished, not yet sawn, products from a MEMS foundry;
ASIC wafer comes in as a finished, not sawn, product from ASIC foundry;

Both wafers (i.e., MEMS and ASIC) are of the same size and have appropriate alignment features so that the MEMS and ASIC wafers can be efficiently aligned with each other; Wafer-alignment features may be some unique marks on both wafers. For example, 3 crosses, in three different places on MEMS wafer and ASIC wafer. They may be placed precisely in the same location (from the same reference point) on the MEMS wafer and the ASIC wafer.

TSVs (Thru Silicon Vias) are created in the ASIC wafer along with a “vent hole” using DRIE (Deep Reactive Ion Etching);
External metallization is deposited on MEMS and ASIC wafers; and
Wafers are aligned and joined together using FOW (Film On Wafer) with via interconnects in-between.

A die in the context of integrated circuits is a small block of semiconducting material, on which a given functional circuit is fabricated. Typically, integrated circuits are produced in large batches on a single wafer of electronic-grade silicon (EGS) or other semiconductor (such as GaAs) through processes such as photolithography. The wafer is cut (“diced”) into many pieces, each containing one copy of the circuit. Each of these pieces is called a die.

There are three commonly used plural forms: dice, dies, and die.

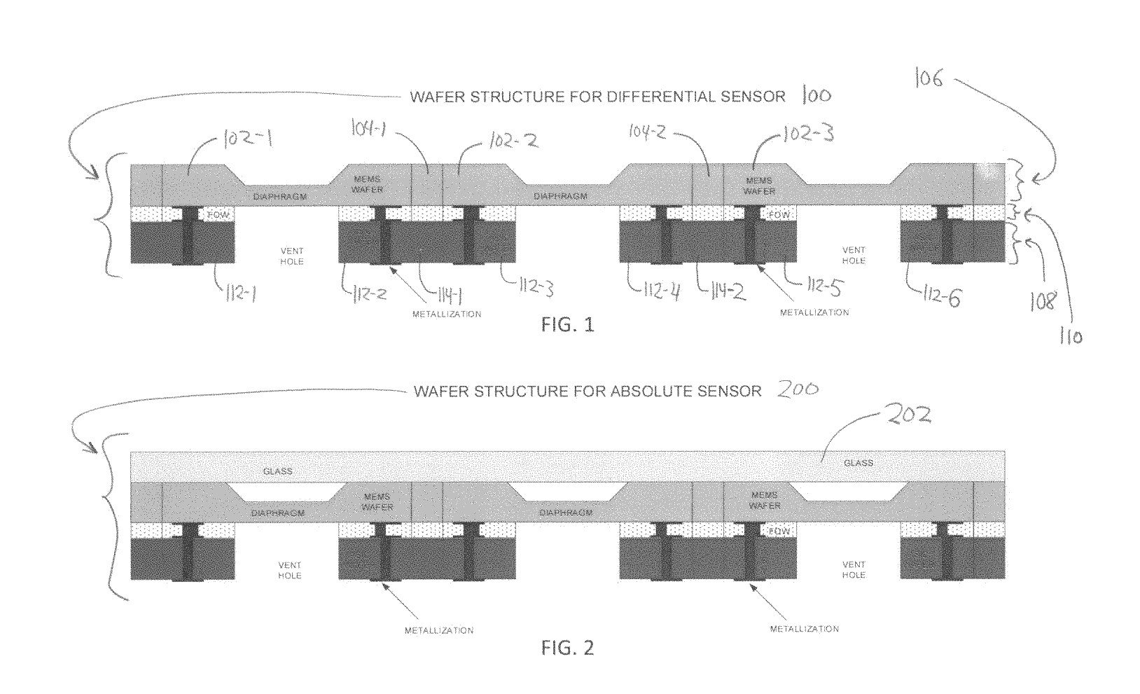

FIG. 1 shows a wafer structure 100 for a differential sensor that can be used for wafer-level calibration of pressure sensors. The wafer structure 100 includes a MEMS wafer 106, which includes MEMS die 102-1, MEMS die 102-2, and MEMS die 102-3, which are separated by MEMS-wafer dicing areas 104-1 and 104-2, which will later (i.e., after wafer-level calibration has been performed) be removed by sawing through the dicing areas 104-1 and 104-2 to separate the MEMS dice 102-1 through 102-3 from one another.

The wafer structure 100 also includes ASIC wafer 108, which, similar to MEMS wafer 106, includes ASIC-wafer dice 112-1 through 112-5. ASIC-wafer dice 112-2 and 112-3 are separated by ASIC-wafer dicing area 114-1, and ASIC-wafer dice 112-4 and 112-5 are separated by ASIC-wafer dicing area 114-2. ASIC-wafer dicing areas 114-1 and 114-2 will later (i.e., after wafer-level calibration has been performed) be removed by sawing through the dicing areas 114-1 and 114-2 to separate ASIC die 112-2 from ASIC die 112-3 and to separate ASIC die 112-4 from ASIC die 112-5, respectively.

The wafer structure 100 also includes Film on Wafer 110, which bonds the MEMS wafer 106 to the ASIC wafer 108.

FIG. 2 shows a wafer structure 200 for an absolute sensor that can be used for wafer-level calibration of pressure sensors. The wafer structure 200 of FIG. 2 is the same as the wafer structure 100 of FIG. 1 except that glass 202 is included above the MEMS wafer.

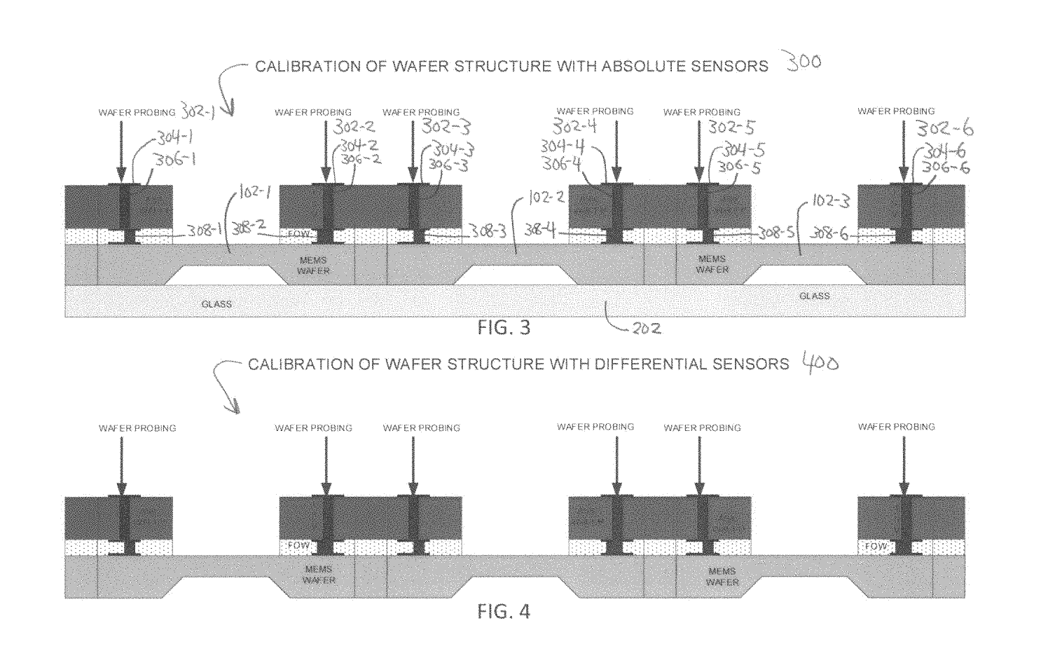

FIG. 3 shows wafer-level calibration 300 of wafer structure 200. As shown in FIG. 3, wafer probing needles 302-1 and 302-2, 302-3 and 302-4, and 302-5 and 302-6, make necessary electrical connections to the ASIC wafer dies respectively, through metallizations 304-1 and 304-2, 304-3 and 304-4, and 304-5 and 304-6 and thru-silicon vias (TSVs) 306-1 and 306-2, 306-3 and 306-4, and 306-5 and 306-6, respectively. Metallizations 308-1 and 308-2, 308-3 and 308-4, and 308-5 and 308-6 represent electrical connections between ASIC and MEMS.

FIG. 4 shows wafer-level calibration 400 of wafer structure 100. FIG. 4 is the same as FIG. 3, except that glass 202 of FIG. 3 is omitted from FIG. 4.

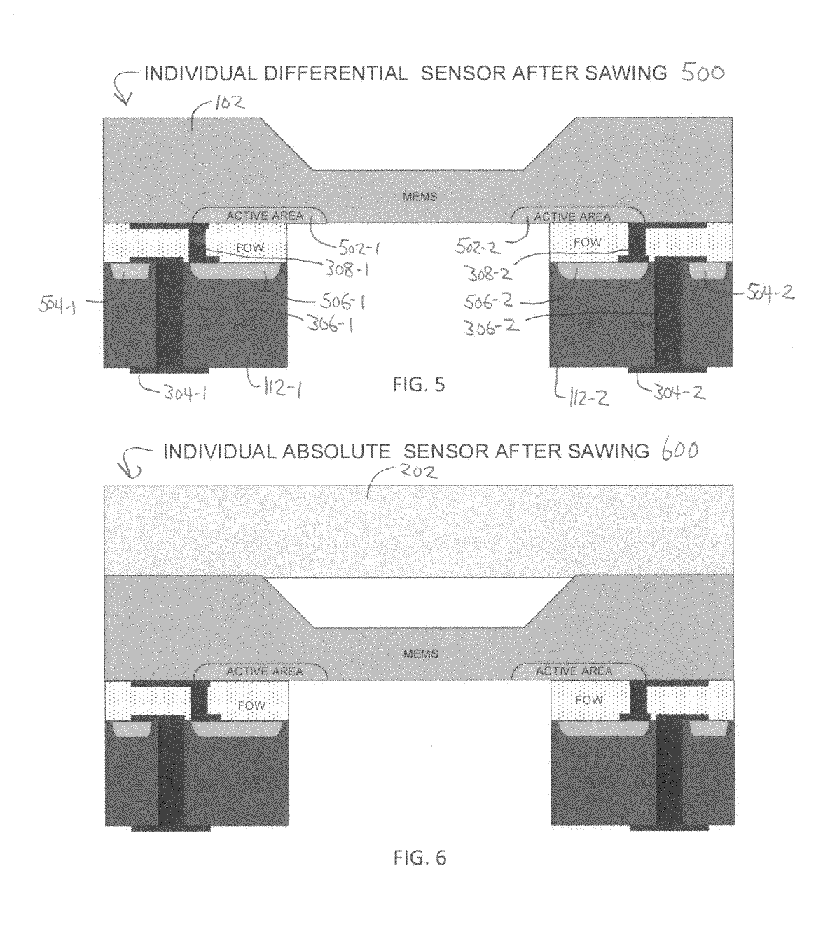

FIG. 5 shows an after-sawing individual differential pressure sensor 500 in accordance with embodiments of the invention. Active area 502 is where actual circuits are made in silicon. In case of MEMS, it will be diffusion area for piezo-resistors and interconnects, which ultimately ends up connected to MEMS metallized pads. In case of ASIC, active areas 504-1, 504-2, 506-1, and 506-2 comprise diffusions that create transistors, resistors, or capacitors, and the like, in other words, ASIC circuitry. ASIC will have metallized pads for connections to MEMS and to the outside world.

FIG. 6 shows an after-sawing individual absolute pressure sensor 600 in accordance with embodiments of the invention. FIG. 6 is the same as FIG. 5 except that glass 202 appears in FIG. 6.

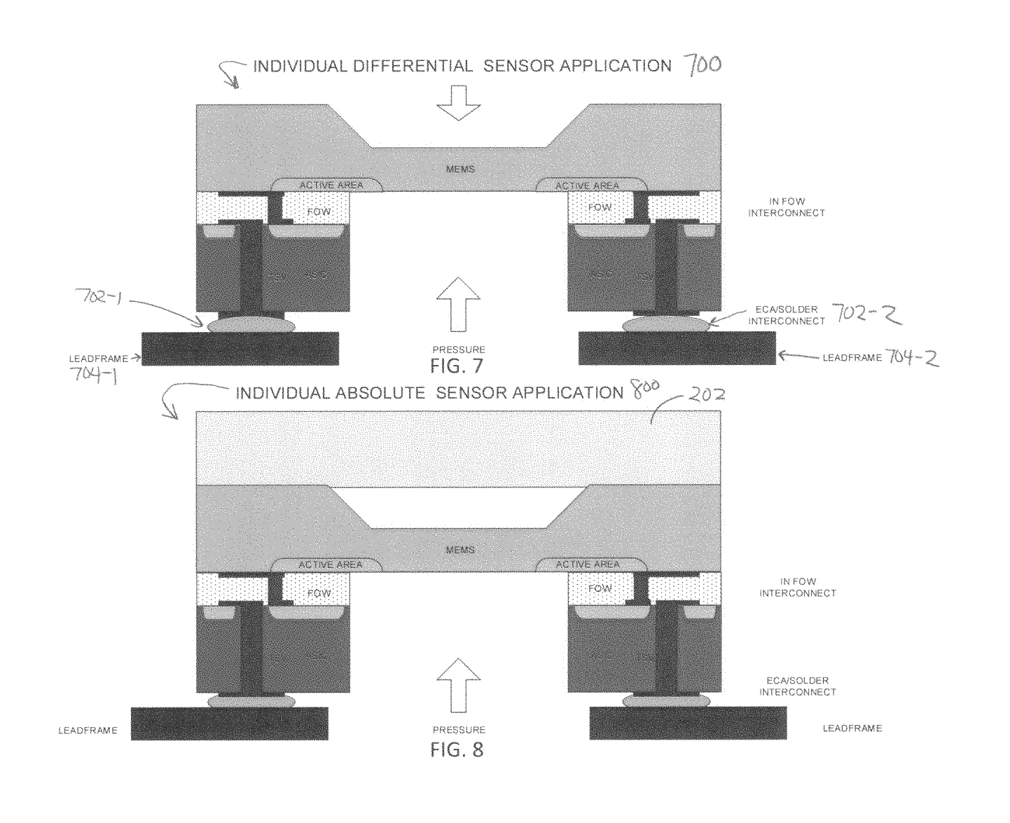

FIG. 7 shows an application 700 of after-sawing individual differential pressure sensor 500 in accordance with embodiments of the invention. FIG. 7 is the same as FIG. 5, except that after-sawing individual differential pressure sensor 500 is bonded and electrically connected to leadframe 704 by electrically conductive adhesive (ECA) 702.

FIG. 8 shows an application 800 of after-sawing individual absolute pressure sensor 600 in accordance with embodiments of the invention. FIG. 8 is the same as FIG. 7 except that glass 202 appears in FIG. 8.

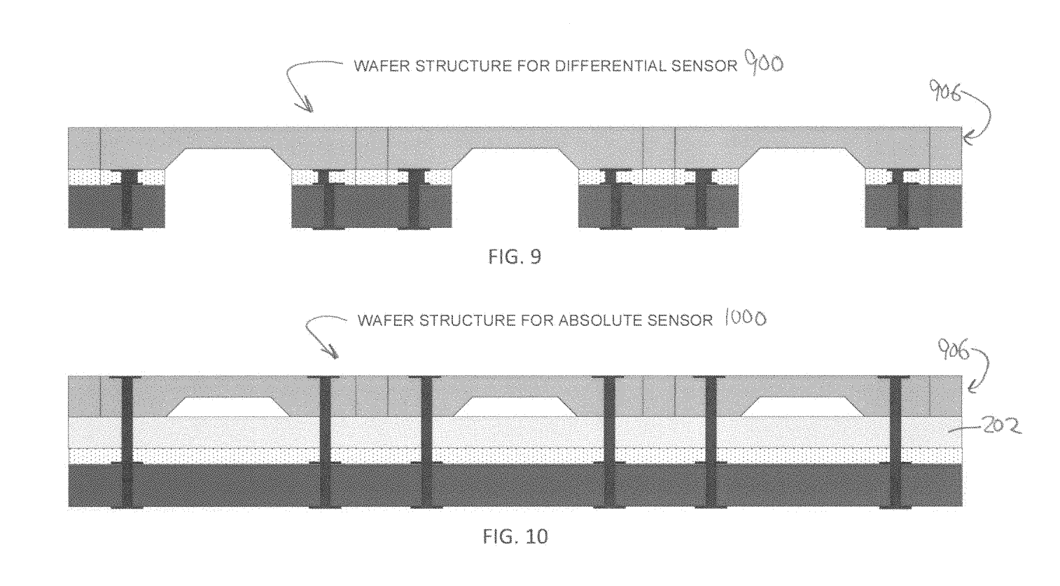

FIG. 9 shows a wafer structure 900 for a differential sensor that can be used for wafer-level calibration of pressure sensors and that is similar to the wafer structure 100 of FIG. 1 except that the MEMS wafer 906 is oriented “up-side down” relative to the MEMS wafer 106 of FIG. 1.

FIG. 10 shows a wafer structure 1000 for an absolute sensor that can be used for wafer-level calibration of pressure sensors and that is similar to the wafer structure 200 of FIG. 2 except that the MEMS wafer 906 is oriented “up-side down” relative to the MEMS wafer of FIG. 2 and that the through-FOW TSVs extend through glass 202 and through the MEMS 906.

Because the MEMS wafers and ASIC wafers are processed (i.e., created) separately from one another, pressure sensors that are configured for wafer-level calibration can be packaged at a significantly reduced cost relative to pressure sensors for which both the MEMS and the ASIC are created on a single die.

While the present invention has been illustrated by a description of various embodiments and while these embodiments have been described in considerable detail, it is not the intention of the applicants to restrict or in any way limit the scope of the appended claims to such detail. Additional advantages and modifications will readily appear to those skilled in the art. The invention in its broader aspects is therefore not limited to the specific details, representative apparatus and method, and illustrative example shown and described. Accordingly, departures may be made from such details without departing from the spirit or scope of applicant's general inventive concept.

1. A wafer structure configured for wafer-level calibration of a plurality of pressure sensors, the wafer structure comprising:
a microelectromechanical systems (MEMS) wafer that includes a plurality of MEMS dice that are separated by a plurality of MEMS-wafer dicing areas;
an application-specific integrated circuit (ASIC) wafer that includes a plurality of ASIC-wafer dice that are separated by a plurality of ASIC-wafer dicing areas;
a Film on Wafer (FOW) that bonds the MEMS wafer to the ASIC wafer;
a plurality of thru silicon vias (TSVs) extending through the ASIC wafer;
a plurality of metallizations extending through the FOW thereby creating an electrical connection between the ASIC wafer and the MEMS wafer thereby enabling wafer-level calibration of the plurality of pressure sensors.

2. The wafer structure of claim 1, wherein the plurality of MEMS-wafer dicing areas are configured to be removed by sawing through the dicing areas, after wafer-level calibration has been performed, in order to separate the MEMS dice from one another.

3. The wafer structure of claim 1, wherein the plurality of ASIC-wafer dicing areas are configured to be removed by sawing through the dicing areas, after wafer-level calibration has been performed, in order to separate the ASIC dice from one another.

4. The wafer structure of claim 1, wherein the MEMS wafer and the ASIC wafer each include alignment features for aligning the MEMS wafer with the ASIC wafer.

5. The wafer structure of claim 4, wherein the MEMS wafer is processed at a MEMS foundry, the ASIC wafer is processed at an ASIC foundry, and the wafer structure is packaged at a packaging foundry, which is separate from the MEMS foundry and separate from the ASIC foundry.
